(19) United States
(12) Patent Application Publication
(10) Pub. No.: US 2002/0098448 A1
(43) Pub. Date: Jul. 25, 2002

(54) Method of producing thin film circuit board

(75) Inventors: Koji Yoshida, Kusatsu-shi (JP); Makoto Tose, Moriyama-shi (JP)

Correspondence Address: OSTROLENK FABER GERB & SOFFEN, 1180 AVENUE OF THE AMERICAS, NEW YORK, NY, 100368403

(73) Assignee: Murata Manufacturing Co., Ltd.

(21) Appl. No.: 10/035,400

(22) Filed: Oct. 26, 2001

(30) Foreign Application Priority Data
Oct. 26, 2000 (JP) 2000-326333

(51) Int. Cl. G03F 7/00

(52) U.S. Cl. 430/311; 430/314; 430/317

(57) ABSTRACT

The present invention provides a thin film circuit board used as a milli-wave or micro-wave module, in which a patterned insulating film having a sufficient thickness can be stably formed. Such an insulating film is produced by the step of forming a conductor film in a predetermined pattern on a cleaned substrate and forming an insulating film on the substrate to cover the conductor film, the step of patterning the insulating film, the step of forming a second insulating film, and the step of patterning the insulating film. In this way, the insulating film forming step and the patterning step are repeated a required number of times.

### BACKGROUND OF THE INVENTION

1. Field of the Invention

The present invention relates to a method of producing a thin film circuit board having a structure comprising a conductor film formed on a substrate, an insulating film formed on the substrate to cover the conductor film. Particularly, the present invention relates to a method of producing a thin film circuit board which constitutes a module used in the milli-wave or micro-wave region.

2. Description of the Related Art

A radio frequency module used in the milli-wave or micro-wave region in the field of radio communication is required to have a small size, low cost and high performance.

The above-described milli-wave or micro-wave module constitutes a thin film circuit board having a structure comprising a substrate, a conductor film formed on the substrate, and an insulating film formed on the substrate to cover the conductor film. When the conductor film is referred to as the “lower conductor film”, and an upper conductor film is formed on the insulating film, the insulating film functions as an interlayer insulating film.

The milli-wave or micro-wave module is required to comprise a transmission line having a low transmission loss and high efficiency. Therefore, a conductive material having low electric resistance is used for the conductor film which provides the transmission line.

The interlayer insulating film formed between the lower conductor film and the upper conductor film is required to be made of a dielectric material having low dielectric constant and low dielectric loss tangent. Therefore, organic resins such as polyimide, a benzocyclobutene resin, an acrylic resin, a cyclic olefin resin, and the like, which have a low dielectric constant and low dielectric loss tangent, are used as materials for the interlayer insulating film.

However, with the interlayer insulating film having a small thickness, unintended electromagnetic coupling occurs between the lower conductor film and the upper conductor film to fail to obtain the intended characteristics in some cases. It is thus desired to increase the thickness of the interlayer insulating film. However, when the insulating film is thickened, particularly, to 20 μm or more, the following problems occur.

The insulating film comprises a photosensitive organic film or a non-photosensitive organic film.

With the insulating film comprising a photosensitive organic film, the steps of (1) formation of a varnish photosensitive organic film, (2) pre-baking, (3) exposure, (4) development, and (5) curing are carried out in order to obtain a patterned insulating film.

In this case, when the photosensitive organic film is thick, the degree of light absorption is increased, and thus light does not reach the bottom of the photosensitive film in the exposure step (3). Therefore, in the development step (4), an undeveloped portion occurs in the case of a positive photosensitive organic film, and peeling easily occurs in the case of a negative photosensitive organic film.

On the other hand, with the insulating film comprising a non-photosensitive organic film, the steps of (1) formation of a varnish non-photosensitive organic film, (2) pre-baking, (3) curing, (4) formation of an etching resist, (5) etching, and (6) separation of the etching resist are carried out in order to obtain a patterned insulating film.

In this case, when the non-photosensitive organic film is thick, great stress occurs in the non-photosensitive organic film to cause cracking or peeling of the non-photosensitive organic film after the curing step (3) in some cases.

### SUMMARY OF THE INVENTION

Accordingly, it is an object of the present invention to provide a method of producing a thin film circuit board which can prevent the occurrence of the above problems even when an insulating film comprising an organic resin is thickened.

The present invention is aimed at a method of producing a thin film circuit board used as a milli-wave or micro-wave module.

The thin film circuit board comprises a substrate, a conductor film formed on the substrate, and an insulating film formed on the substrate to cover the conductor film.

The substrate comprises dielectric ceramic, and has a thickness of 0.05 mm to 2 mm and a flexural strength of 500 kgf/cm² to 4000 kgf/cm².

The reason why the substrate comprises dielectric ceramic as described above is an attempt to miniaturize the thin film circuit board by increasing the dielectric constant of the substrate. The reason for setting the thickness of the substrate to 0.05 mm or greater is that the mechanical strength of the substrate is kept at a predetermined level or higher. On the other hand, in consideration of the fact that coupling between respective elements increases as the thickness of the substrate increases, the maximum allowable thickness in the milli-wave or micro-wave region is 2 mm. The reason for setting the flexural strength to 500 kgf/cm² to 4000 kgf/cm² is that a range causing no breakage of the substrate is defined for carrying out the production method of the present invention.

The conductor film comprises at least one selected from Cu, Au, Ag, Ni, Cr, Al, Ni, Ti, Cr, Ni—Cr, Nb, V.

The insulating film comprises at least one organic resin selected from polyimide, epoxy resins, benzocyclobutene resins, acrylic resins, and cyclic olefin resins, and has a thickness of 20 μm or greater, an area of 5 cm² or less per pattern, and a stress of 15 MPa to 60 MPa.

The reason for setting the thickness of the insulating film to 20 μm or greater is that in isolation between conductor films by the insulating film, the minimum thickness with which isolation can be made in the milli-wave or micro-wave region is 20 μm. The reason for setting the area per pattern to 5 cm² or less is that the maximum area with which the insulating film exhibits the advantage of miniaturizing the thin film circuit board is 5 cm². The reason for setting the stress of the insulating film to 15 MPa to 60 MPa is that the stress of general films made of the above-described resins is in this range.

In order to solve the above-described problems, a method of producing the thin film circuit board having the above arrangement according to the present invention comprises the steps of cleaning the substrate, forming the conductor film in a predetermined pattern on the substrate, forming the insulating film on the substrate to cover the conductor film, patterning the insulating film, and repeating the insulating film forming step and the insulating film patterning step more than once.

In a case where the insulating film comprises a photosensitive organic film, the insulating film forming step preferably comprises a step of forming the varnish-like photosensitive organic film on the substrate, and the patterning step preferably comprises steps of exposing and developing the photosensitive organic film by photolithography, and curing the photosensitive organic film.

In a case where the insulating film comprises a non-photosensitive organic film, the insulating film forming step preferably comprises a step of forming the varnish-like non-photosensitive organic film on the substrate, and the patterning step preferably comprises steps of curing the non-photosensitive organic film, forming an etching resist on the non-photosensitive organic film, etching the non-photosensitive organic film by dry etching, and removing the etching resist.

### BRIEF DESCRIPTION OF THE DRAWINGS

FIG. 1 is a sectional view schematically illustrating in order the representative steps of a method of producing a thin film circuit board according to an embodiment of the present invention; and

FIG. 2 is a sectional view schematically illustrating in order the representative steps of a method of producing a thin film circuit board according to another embodiment of the present invention.

### DESCRIPTION OF THE PREFERRED EMBODIMENTS

The present invention will be described below with reference to embodiments. In the embodiments, Cu is used as a material for a conductor film, and polyimide is used for an insulating film. However, materials are not limited to these materials.

In the first embodiment, photosensitive polyimide is used for forming an insulating film.

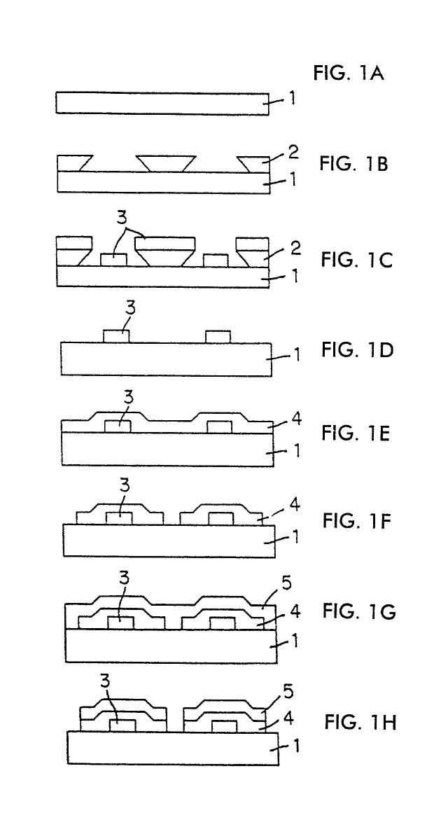

As shown in FIG. 1A, a substrate 1 is prepared. The substrate 1 comprises, for example, dielectric ceramic such as alumina or the like. The thickness of the substrate 1 is 0.05 mm to 2 mm, and the flexural strength is 500 kgf/cm² to 4000 kgf/cm².

Next, the substrate 1 is cleaned. Cleaning is performed by plasma ashing or surface cleaning with an organic solvent such as acetone, isopropyl alcohol, methanol, ethanol, or the like.

Next, as shown in FIG. 1B, a lift off resist pattern 2 is formed on the substrate 1. The lift off resist pattern 2 is formed by, for example, a chlorobenzene method.

In detail, a positive resist for a thick film (for example, “AZP4620” produced by Clariant Corporation) is first formed to a thickness of 6 μm on benzocyclobutene by spin coating at 1500 rpm×30 seconds, and then pre-baked in a clean oven of 90° C. for 30 minutes. Then, the substrate 1 is dipped in chlorobenzene kept at about 40° C. for 10 minutes to form a developer insolubilized layer on the resist surface, and then placed on a hot plate of 90° C. for 90 seconds to evaporate excessive chlorobenzene. Next, exposure is performed with an h ray by a contact exposure device, and then the substrate 1 is dipped in an alkali developer (for example, “AZ400K” produced by Clariant Corporation) for 2 minutes. The substrate 1 on which the lift off resist pattern 2 is formed by the above steps is cleaned with pure water for 5 minutes or more, and then dried by a spin dryer.

Next, as shown in FIG. 1C, the substrate 1 is placed in a vacuum evaporation apparatus in which Ti is first deposited to a thickness of 100 nm to form a layer adhered to the substrate 1, and Cu is then deposited to a thickness of 5 μm. Thus a conductor film 3 is formed in a predetermined pattern on the substrate 1. The conductor film 3 is formed not only on the substrate 1 but also on the lift off resist pattern 2.

Next, as shown in FIG. 1D, the substrate 1 is dipped in, for example, acetone, and ultrasonic waves are further applied to the substrate 1 to remove (lift off) the excessive lift off resist pattern 2 and the conductor film 3 formed thereon.

Next, as shown in FIG. 1E, an adhesion improver such as 3-aminopropylsilane or the like is coated on the substrate 1, and then varnish-like negative photosensitive polyimide (for example, “Photoneece UR-3180E” produced by Toray Co., Ltd.) is coated by spin coating at 2150 rpm for 30 seconds. Then, the substrate 1 is pre-baked by using the hot plate at 60° C. for 6 minutes, at 80° C. for 6 minutes and 100° C. for 6 minutes to form a photosensitive polyimide film 4 on the substrate 1 to cover the conductive film 3.

Next, the photosensitive polyimide film 4 is irradiated with an h ray of 400 mJ/cm² by using the contact exposure device, and then the substrate 1 is dipped in a polyimide developer (for example, “DV-605” produced by Toray Co., Ltd.) for 7.5 minutes to remove unexposed portions of the photosensitive polyimide film 4, thereby obtaining the photosensitive polyimide film 4 having a pattern area of, for example, 4 cm², as shown in FIG. 1F Next, the photosensitive polyimide film 4 patterned as described above is cured at 400° C. for 1 hour in a nitrogen atmosphere having an oxygen concentration of 100 ppm or less to thermally polymerize the polyimide. The photosensitive polyimide film 4 obtained in this step has a thickness of, for example, 15 μm.

Next, substantially the same steps as shown in FIGS. 1E and 1F are repeated to form a second photosensitive polyimide film 5 as shown in FIG. 1G, and then the second photosensitive polyimide film 5 is patterned as shown in FIG. 1H.

Then, the step of forming the photosensitive polyimide film and the patterning step are repeated a necessary number of times to obtain a photosensitive polyimide film having a total thickness of, for example, 30 μm or more.

In the second embodiment, non-photosensitive polyimide is used for forming an insulating film.

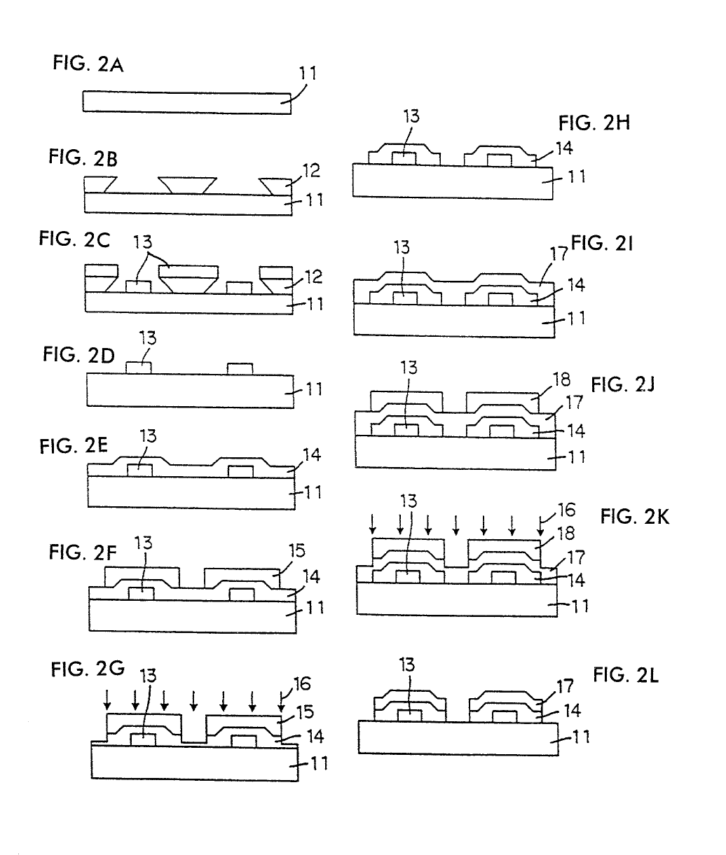

The step of preparing a substrate 11 and cleaning it as shown in FIG. 2A, the step of forming a lift off resist pattern 12 on the substrate 11 as shown in FIG. 2B, the step of forming a conductor film 13 on the substrate 11 as shown in FIG. 2C, and the step of lifting off the excessive lift off resist pattern 12 and the conductor film 13 formed thereon as shown in FIG. 2D are carried out based on the same method as the first embodiment.

Next, as shown in FIG. 2E, an adhesion improver such as 3-aminopropylsilane or the like is coated on the substrate 11, and then varnish-like non-photosensitive polyimide (“OPI-N3205” produced by Hitachi Kasei Co., Ltd.) is coated by spin coating at 1000 rpm for 30 seconds, and then thermally polymerized by curing at 100° C. for 30 minutes, 200° C. for 30 minutes and 350° C. for 60 minutes in a nitrogen atmosphere with an oxygen content of 100 ppm or less to form a non-photosensitive polyimide film 14.

Next, as shown in FIG. 2F, an etching resist 15 is formed on the non-photosensitive polyimide film 14.

In more detail, a positive resist thick film (for example, “AZ46201” produced by Clariant Corporation) is first deposited to a thickness of 6 μm by spin coating at 1500 rpm for 30 seconds, and then pre-baked in a clean oven of 90° C. for 30 seconds. Then, the substrate 11 exposed to the h ray by using a contact exposure device, and dipped in an alkali developer (for example, “AZ400K” produced by Clariant Corporation) for 2 minutes. The etching resist 15 patterned by these steps is washed with pure water for 5 minutes, and dried by a spin dryer.

Next, as shown in FIG. 2G, the non-photosensitive polyimide film 14 is etched. For example, etching 16 is performed for 15 minutes by using a reactive ion etching (RIE) apparatus under the conditions including an O₂ gas flow rate of 140 sccm, a CF₄ gas flow rate of 60 sccm, a pressure of 0.4 Torr, and RF power of 300 W. As a result, the non-photosensitive polyimide film 14 patterned to have a pattern area of 4 cm² is provided on the substrate 11.

Next, as shown in FIG. 2H, the etching resist 15 is separated with acetone. In this way, the patterned non-photosensitive polyimide film 14 having a thickness of, for example, 12 μm can be obtained.

Next, as shown in FIGS. 2I to 2L, substantially the same steps as shown in FIGS. 2E to 2H are repeated. Namely, as shown in FIG. 2I, a second non-photosensitive polyimide film 17 is formed, and as shown in FIG. 2J, a second etching resist 18 is formed, and then patterned. Then, as shown in FIG. 2K, etching 16 is again performed to form the patterned second non-photosensitive polyimide film 17 on the first non-photosensitive polyimide film 14, as shown in FIG. 2L.

The above-described steps of forming the non-photosensitive polyimide film and patterning the film are repeated a necessary number of times to obtain a non-photosensitive polyimide film having a total thickness of, for example, 24 μm or more.

As described above, in the present invention, thin insulating films having a relatively small thickness are stacked while patterning to obtain a relatively thick insulating film having a thickness of, for example, 20 μm or more. Therefore, an insulating film having a relatively large thickness can be formed in a thin film circuit board without causing undeveloped portions, cracking or peeling.

Therefore, in a thin film circuit board used as a milli-wave or micro-wave module, the thickness of an interlayer insulating film formed between an upper conductor film and a lower conductor film can be sufficiently increased to prevent electromagnetic coupling between the upper and lower conductor films, thereby easily achieving the intended characteristics of the milli-wave or micro-wave module.

What is claimed is:

1. A method of producing a thin film circuit board used as a milli-wave or micro-wave module, the method comprising steps of:
cleaning a substrate comprising dielectric ceramic, and having a thickness of 0.05 mm to 2 mm and a flexural strength of 500 kgf/cm² to 4000 kgf/cm²;
forming a conductor film in a predetermined pattern on the substrate, said conductor film including at least one selected from Cu, Au, Ag, Ni, Cr, Al, Ni, Ti, Cr, Ni—Cr, Nb, V;
forming a insulating film on the substrate to cover the conductor film, said insulating film comprising at least one organic resin selected from polyimide, epoxy resins, benzocyclobutene resins, acrylic resins, and cyclic olefin resins, and having a thickness of 20 μm or greater, an area of 5 cm² or less per pattern, and a stress of 15 MPa to 60 MPa;
patterning the insulating film; and
repeating the insulating film forming step and the insulating film patterning step more than once.

2. A method of producing a thin film circuit board according to claim 1, wherein the insulating film comprises a photosensitive organic film,
said insulating film forming step comprises a step of forming the varnish-like photosensitive organic film on the substrate, and
said patterning step comprises steps of
exposing and developing the photosensitive organic film by photolithography, and
curing the photosensitive organic film.

3. A method of producing a thin film circuit board according to claim 1, wherein the insulating film comprises a non-photosensitive organic film,
said insulating film forming step comprises a step of forming the varnish-like non-photosensitive organic film on the substrate, and
said patterning step comprises steps of
curing the non-photosensitive organic film,
forming an etching resist on the non-photosensitive organic film,
etching the non-photosensitive organic film by dry etching, and
removing the etching resist.
